(19) United States
(12) Patent Application Publication
(10) Pub. No.: US 2022/0159258 A1
(43) Pub. Date: May 19, 2022

(54) GENERALIZED BYPASS BINS AND APPLICATIONS FOR ENTROPY CODING

(71) Applicant: INTEL CORPORATION, Santa Clara, CA (US)

(72) Inventors: Alexander Alshin, Moscow (RU); Jill Boyce, Portland, OR (US); Pavel Frolov, Moscow (RU); Vasily Aristarkhov, Nizhny Novgorod (RU)

(73) Assignee: INTEL CORPORATION, Santa Clara, CA (US)

(21) Appl. No.: 17/441,211

(22) PCT Filed: Jun. 22, 2020
(86) PCT No.: PCT/US2020/038894

§ 371 Date: Sep. 20, 2021

Related U.S. Application Data
(60) Provisional application No. 62/866,110, filed on Jun. 25, 2019.

(51) Int. Cl. H04N 19/13; H04N 19/91; H04N 19/149; H04N 19/184

(52) U.S. Cl. CPC H04N 19/13; H04N 19/184; H04N 19/149; H04N 19/91

(57) ABSTRACT

An embodiment of a video codec may include technology to store video data, and utilize a generalized bypass bin to one or more of encode and decode the video data. Other embodiments are disclosed and claimed.

### CLAIM FOR PRIORITY

This application claims priority to U.S. Provisional Patent Application No. 62/866,110, filed Jun. 25, 2019 and titled GENERALIZED BYPASS BINS AND APPLICATIONS FOR ENTROPY CODING, which is incorporated by references in its entirety for all purposes.

### BACKGROUND

Video encoding and decoding is useful to reduce the amount of data that is transmitted to process video information. A video codec refers to an electronic circuit or software that compresses or decompresses digital video. For example, a video codec converts uncompressed video to a compressed format or decompresses a compressed format to uncompressed video. Examples of compressed video formats include MP4, 3GP, OGG, WMV, FLV, AVI, MPEG-2 PS, MPEG, VOB, VP9, among numerous others. Example video codecs include H.264, high-efficiency video coding (HEVC), MPEG-4, QUICKTIME, DV, among numerous others.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is an illustrative table of a PIPE encoding scheme;

FIG. 1B is an illustrative graph of probability versus bins for the PIPE encoding scheme;

FIG. 2A is an illustrative graph of two estimator values versus time after initialization;

FIG. 2B is an illustrative graph of two estimator values versus time after convergence;

FIG. 3 is an illustrative graph of frequency of use versus context model;

FIG. 4 is an illustrative graph of a generalized pass mesh according to an embodiment;

FIG. 5 is a flowchart of an example of a method of encoding a context bin according to an embodiment;

FIG. 6 is a flowchart of an example of a method of encoding a generalized pass according to an embodiment;

FIG. 7 is a flowchart of an example of a method of decoding a context bin according to an embodiment;

FIG. 8 is a flowchart of an example of a method of decoding a generalized pass according to an embodiment;

FIG. 9 is a flowchart of an example of a method of encoding a generalized pass with probability ½\hat{ }k according to an embodiment;

FIG. 10 is an illustrative graph of a probability versus bins for a generalized pass, a bypass pass, and a Shannon limit according to an embodiment;

FIG. 11 is an illustrative graph of average bits for a general case of a generalized pass with a probability of ½ⁿ according to an embodiment;

FIG. 12 is a block diagram of an example of an electronic system according to an embodiment;

FIG. 13 is a block diagram of an example of an electronic apparatus according to an embodiment;

FIG. 14 is a flowchart of an example of a method of processing video data according to an embodiment;

FIG. 15 is an illustrative diagram of an example system; and

FIG. 16 illustrates an example small form factor device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

While the following description sets forth various implementations that may be manifested in architectures such as system-on-a-chip (SoC) architectures for example, implementation of the techniques and/or arrangements described herein are not restricted to particular architectures and/or computing systems and may be implemented by any architecture and/or computing system for similar purposes. For instance, various architectures employing, for example, multiple integrated circuit (IC) chips and/or packages, and/or various computing devices and/or consumer electronic (CE) devices such as set top boxes, smartphones, etc., may implement the techniques and/or arrangements described herein. Further, while the following description may set forth numerous specific details such as logic implementations, types and interrelationships of system components, logic partitioning/integration choices, etc., claimed subject matter may be practiced without such specific details. In other instances, some material such as, for example, control structures and full software instruction sequences, may not be shown in detail in order not to obscure the material disclosed herein.

The material disclosed herein may be implemented in hardware, firmware, software, or any combination thereof. The material disclosed herein may also be implemented as instructions stored on a machine-readable medium, which may be read and executed by one or more processors. A machine-readable medium may include any medium and/or mechanism for storing or transmitting information in a form readable by a machine (e.g., a computing device). For example, a machine-readable medium may include read only memory (ROM); random access memory (RAM); magnetic disk storage media; optical storage media; flash memory devices;

electrical, optical, acoustical or other forms of propagated signals (e.g., carrier waves, infrared signals, digital signals, etc.), and others.

References in the specification to “one implementation”, “an implementation”, “an example implementation”, etc., indicate that the implementation described may include a particular feature, structure, or characteristic, but every embodiment may not necessarily include the particular feature, structure, or characteristic. Moreover, such phrases are not necessarily referring to the same implementation. Further, when a particular feature, structure, or characteristic is described in connection with an embodiment, it is submitted that it is within the knowledge of one skilled in the art to effect such feature, structure, or characteristic in connection with other implementations whether or not explicitly described herein.

Methods, devices, systems, and articles are described herein related to video systems. More particularly, embodiments relate to generalized bypass bins and their application for entropy coding.

Advantageously, some embodiments may provide a reduction of the number of context models in arithmetic coding for video compression, which reduces look-up table size and memory for probability storage. Some embodiments may further provide simplification of renormalization and interval division (e.g., in a video system).

HEVC CABAC (Context Adaptive Binary Arithmetic Coding) is used to losslessly encode symbols in a video codec. Each symbol may either be context coded or coded in bypass mode. Arithmetic coding is based on a Range division. If after another division the Range becomes less than 256, then renormalization is needed which is multiplication by two until the value of the Range returns to 256<=Range<512. These operations are most simple for a bypass mode when the Range is divided by two and the following renormalization (which includes multiplication by two) returns the Range to its initial value. Thus for bypass mode after division and renormalization, the Range does not change and these operations can be omitted. Bypass mode is a most simple way to write a bin to a bit stream. A drawback, however, is that bypass mode cannot compress data. A number of bins is always equal to a number of bits. On the contrary, a context bin allows additional compression to be reached due to adaptation to local statistics. Division of the range is determined by local probability for a symbol. Probability estimation is carried out after encoding/decoding of each context bin, where every contest model has to store and update probability. For CABAC in H.264/HEVC, for example, seven (7) bits are needed (e.g., Versatile Video Coding (VVC) 3 bytes).

In GOOGLE's video codec/coding format VP9, arithmetic coding is also used. Probabilities are known in advance and they are written in the tables.

There are no updates after each symbol encoding/decoding.

The VVC specification may use entropy coding that is similar to HEVC's CABAC, except probability estimation may be different. In an example VVC specification, there may be 424 context models which may correspond to 65 different types of data starting with SplitFlag and ending with TsResidualSign. The 100 rarest context models process only 0.5% of the context bins. Having a large number of context models increases implementation complexity in a video encoder or decoder. Advantageously, some embodiments may provide a generalized bypass for some data types, including some of the data types referred to in the VCC specification.

Some embodiments may provide a generalized bypass which has better coding efficiency compared to the conventional bypass mode. Use of embodiments of the generalized bypass described herein reduces the complexity of a video encoder or decoder implementation by replacing many context models with a generalized bypass, which is simpler to implement. Some embodiments may be included as part of a video standard, such as the VVC standard, and may advantageously reduce complexity of implementation of video encoder and decoder products based on the standard.

In some embodiments, a method of video decoding is provided that includes processing of bit streams that were obtained using binary arithmetic coding. Encoding of rare syntax elements using context bins may not be justified. On the other hand, an application of bypass bins for such syntax cannot provide compression benefits. Some embodiments may provide a set of generalized bypass bins, where each generalized bypass bin corresponds to probability ½\hat{ }n (e.g., (½)ⁿ). Some embodiments advantageously allow a video system to simplify an interval subdivision and renormalization procedure to avoid using look-up tables (LUTs) and to reduce memory resources for probability storage. The choice of type for a generalized bypass bin depends on QP and type of frame/slice.

Entropy coding generally refers to coding without loss. That is, coding with the possibility of lossless decoding for a sequence of elements having, generally speaking, different probabilities of occurrence. As a result, the amount of encoded data decreases on average. Huffman codes are an example of entropy encoding a practical, working arithmetic coding schemes. Further improvement of entropy coding may be achieved through context modeling.

Conventional codecs have to encode a huge amount of different data, which allow introduction of a dependence on the context including, for example, previously encoded symbols. In fact, there is a substitution of the probability for conditional probability. The data that needs to be coded is distributed according to the context models. The probabilities are evaluated within each model independently. Effective context modeling is one of the main methods for improving entropy compression. This is the approach which is most frequently used in some conventional video coding schemes. For example CABAC may utilize entropy coding in H.264 and H.265 (e.g., also referred to as HEVC). CABAC uses three types of bins: a context bin, a bypass bin and a terminated bin. For the context bin, the adaptive estimation for probability is carried out using a look-up table which may take into account changes of local statistics. Coding with per-symbol adaptability has many benefits, however coding with constant probabilities also applies.

For example, VP9 uses a binary arithmetic coding. For each type of data, probabilities are known in advance and they are written in the tables. The probabilities can be updated but only once before starting of coding next frame. This approach is different from H.264 and H.265 because probability is updated every symbol in CABAC. The probabilities in VP9 remain unchanged during the encoding/decoding of each frame. The only one option to utilize adaptability is to change probabilities frame based.

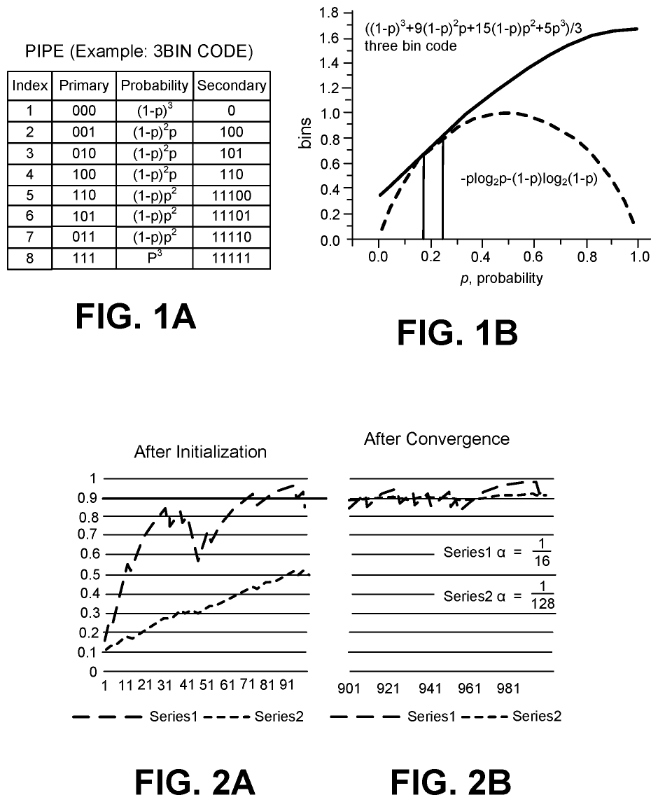

Another example is probability interval partitioning entropy (PIPE) proposed by Heinrich Hertz Institute (HHI). This technology utilizes adaptive probability estimation for each bin, then it is assigned to different pipes according to probability. Every pipe is encoded and decoded independently using specially designed codes. These codes are optimal for small range of probability. It may be considered that probability is constant inside every pipe. FIG. 1A shows an example of 3 bin PIPE code. FIG. 1B shows an example graph of probability versus bins for a pipe encoding scheme.

Redundant Context Models Removal Examples

The use of context models causes additional compression gain. In fact, there is a substitution of the probability for conditional probability. The data that needs to be coded is distributed according to the context models. However if the number of bins inside the context model is small it does not always make sense. The number of updates is not enough to converge from an initial probability to an optimal value. If an exponential smoothing technique is used for probability estimation (where “y” refers to a current bin):

P_{new}=αy+(1−α)P_{old}

then N=1/α is usually considered as the number of updates which is needed to reach an optimal probability. More precisely, this number of updates is needed to reduce error of initialization e-times (e=2.718281 . . . ). Also, the number N describes how many of previously encoded bins have significant influence to the current probability estimation. For CABAC, N=19.69 (e.g., meaning that about 20 preceding bins are taken into account in a probability update process). Note that a majority of the context models have positive autocorrelation in this case the use of two estimations with different a is more effective. If two estimators with α1, α2 are calculated, and their mixture is used for final probability estimation, the similar number of updates is N=2/(α1+α2).

The process of convergence is shown in FIGS. 2A and 2B.

Thus using context bins for data where the number of updates is less than a few dozen for a frame is not effective. The error of initialization does not allow effective compression of such data and also the impact of these context models to total bit-size is insignificant.

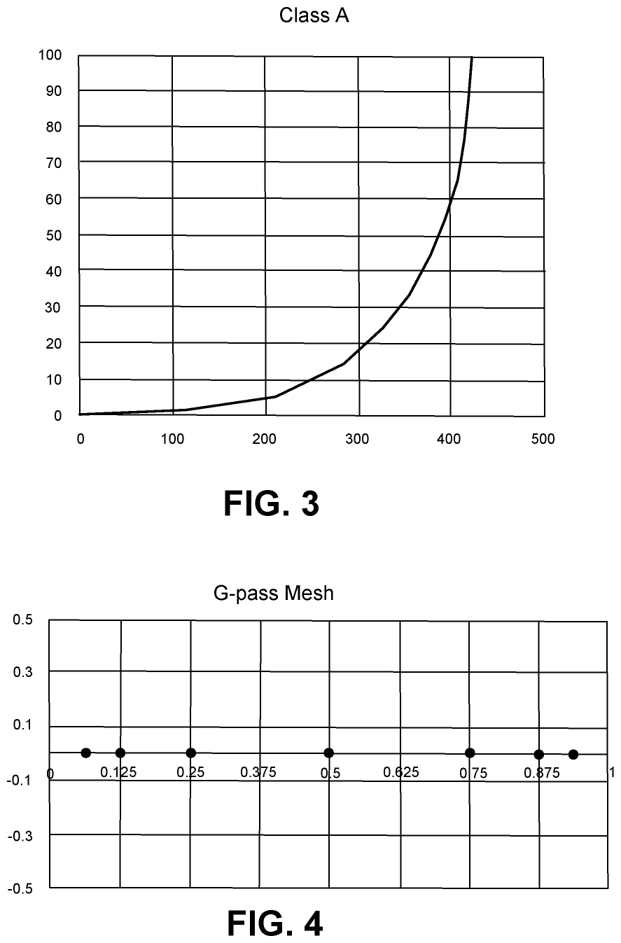

In order to determine which context model(s) can be removed, significant and reliable statistical analysis with regard to number of updates in each context model may be carried out. Some reference software may consist of 424 context models. However frequency of use of the various context models may be quite different. Some of them are updated thousands times for a frame/slice when others have only a few updates. For example, FIG. 3 shows an example graph of Random Access test cumulative statistics for the 424 context models.

Accordingly, the first 250 rarest context models considered together process about 10% while the remaining 174 context models are responsible for about 90% of total context bins. If the first 100 rarest context models are considered together they process only about 0.5% of the bins. The ratio of the number of updates for the most frequent context model to the rarest is about 69,000:1.

Generalized Bypass (G-Pass) Examples

If the rare context models are removed, their bins may be substituted for bypass bins. If the probability is much different from one half (½), however, the use of bypass bins may cause reduction of the compression level. Bypass bins have the simplest realization. There is set of numbers among all possible probabilities that has almost all good points of bypass: (¼, ¾), (¾, ¼); (⅛, ⅞), (⅞, ⅛) . . . (½\hat{ }n, 1−½\hat{ }n), (1−½\hat{ }n, ½\hat{ }n) etc.

FIG. 4 is an illustrative graph of a G-pass mesh.

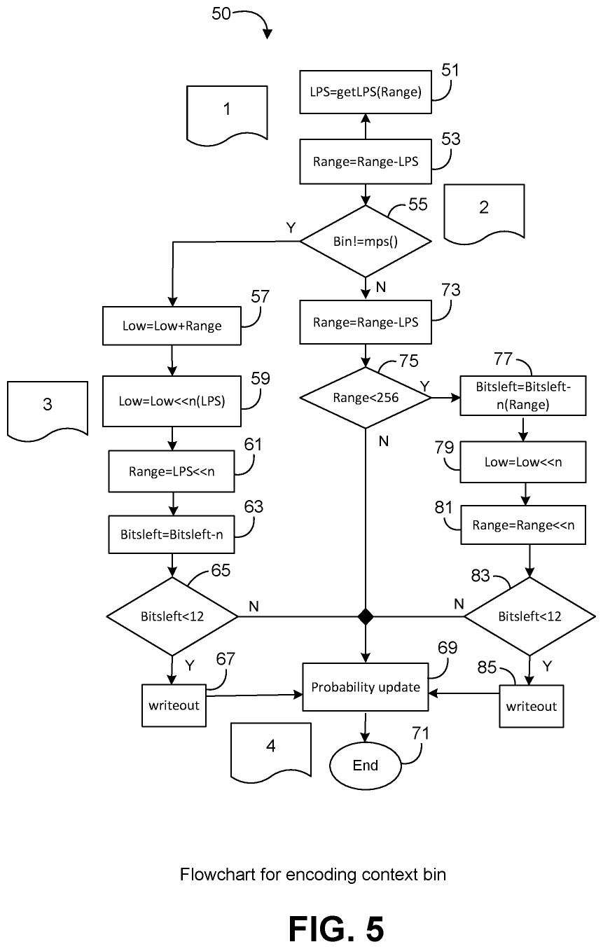

With reference to FIG. 5, an embodiment of a method 50 of encoding a context bin may include setting least probability symbol (LPS)=getLPS(Range) at block 51, and setting Range=Range−LPS at block 53. After block 53, the method 50 may including determining if Bin!=mps( ) at block 55 (most probability symbol) and, if so, setting Low=Low+Range at block 57, setting Low=Low<<n(LPS) at block 59, setting Range=LPS<<n at block 61, and setting Bitsleft=Bitsleft−n at block 63. After block 63, the method 50 may include determining if Bitsleft<12 at block 65 and, if so, performing a writeout at block 67. After block 67, the method 50 may include performing a probability update at block 69 before ending at block 71. If Bitsleft is not <12 at block 65, the method 50 may proceed to performing a probability update at block 69 before ending at block 71.

If Bin=mps( ) at block 55, the method 50 may proceed to setting Range=Range−LPS at block 73. After block 73, the method 50 may include determining if Range<256 at block 75 and, if so, setting Bitsleft=Bitsleft−n(Range) at block 77, setting Low=Low<<n at block 79, and setting Range=Range<<n at block 81. If Range is not <256 at block 75, the method 50 may proceed to performing a probability update at block 69 before ending at block 71. After block 81, the method 50 may include determining if Bitsleft<12 at block 83 and, if so, performing a writeout at block 85. After block 85, the method 50 may include performing a probability update at block 69 before ending at block 71. If Bitsleft is not <12 at block 83, the method 50 may proceed to performing a probability update at block 69 before ending at block 71.

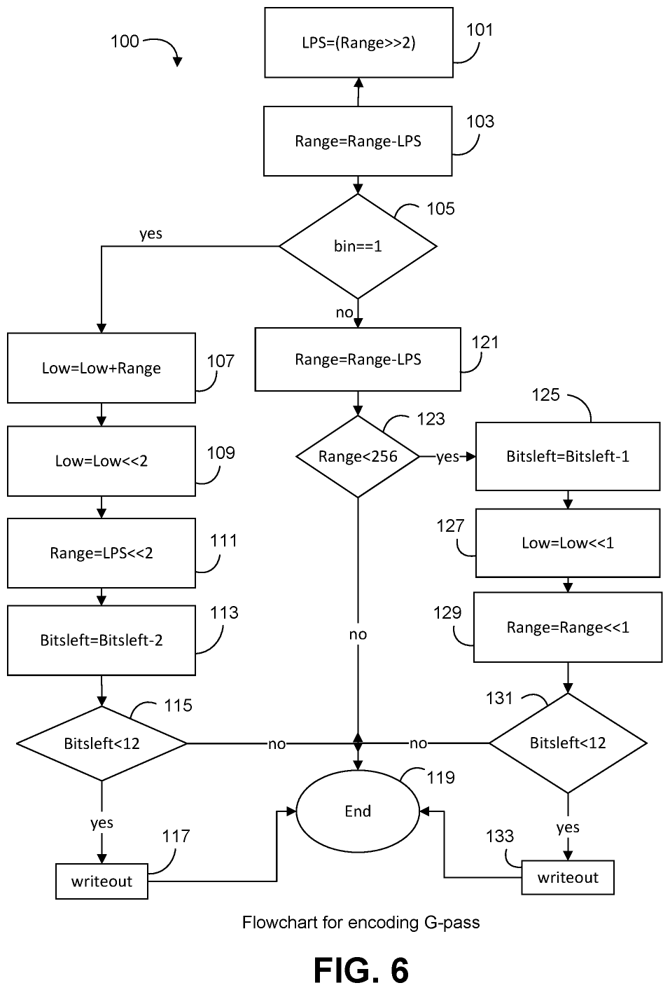

With reference to FIG. 6, an embodiment of a method 100 of encoding a G-pass may include setting LPS=(Range>>2) at block 101 and setting Range=Range−LPS at block 103. After block 103, the method 100 may include determining if bin==1 at block 105 and, if so, setting Low=Low+Range at block 107, setting Low=Low<<2 at block 109, setting Range=LPS<<2 at block 111, and setting Bitsleft=Bitsleft−2 at block 113. After block 113, the method 100 may include determining if Bitsleft<12 at block 115 and, if so, performing a writeout at block 117 before ending at block 119 (e.g., without performing a probability update). If Bitsleft is not <12 at block 115, the method 100 may proceed to ending at block 119.

If the condition does not attain at block 105, the method 100 may proceed to setting Range=Range−LPS at block 121. After block 121, the method 100 may include determining if Range<256 at block 123 and, if so, setting Bitsleft=Bitsleft−1 at block 125, setting Low=Low<<1 at block 127, and setting Range=Range<<1 at block 129. If Range is not <256 at block 123, the method 100 may proceed to ending at block 119. After block 129, the method 100 may include determining if Bitsleft<12 at block 131 and, if so, performing a writeout at block 133 before ending at block 119. If Bitsleft is not <12 at block 131, the method 100 may proceed to ending at block 119.

Table 1 shows a complexity comparison between encoding the G-pass and the context bin, with some main differences marked as 1, 2, 3, and 4 in the respective flowchart.

TABLE 1

| Context bin | | G-pass (1/4) | |
|---|---|---|---|
| 1. | For LPS first quantized probability | 1. | For LPS one shift is needed |
| | value q is needed one summation, one | | LPS=range>>2 |
| | shift and one condition check: if | | |
| | (q & 0x80) q = q \hat{ } 0xff; | | |
| Then LPS= ((q>>2) * (range>>5)>> 1) + 4; | | | |
| Three shifts, one multiplication one | | | |
| summation. LUT can be used but still two | | | |
| shifts is needed. | | | |
| 2. | For condition check MPS (most | 2. | Condition check w ith “1” |
| | probable symbol) should be calculated. | | |
| | Two shift and one summation is needed. | | |
| 3. | For renormalization number of bits | 3. | For renormalization number of bits is |
| | should be calculated using LUT | | always “2”. |
| | | Additional complexity reduction is possible | |
| | | Range=(Range>>2)<<2 can be substituted | |
| | | for Range = Range &508. Which one is better | |
| | | depends on h/w. | |
| 4. | Three bytes are needed for probability | 4. | There is no probability update and |
| | storage. Two probability estimation with | | memory for probability storage. |
| | two different context dependent window | | |
| | size are needed. | | |

Advantageously, for the G-pass, Range division is simpler (one shift), renormalization is always with a default number of bits, no probability update is needed, and no memory is needed for probability storage.

Table 2 shows a comparison of bypass, G-pass, and context bins:

TABLE 2

| | | | | | Simul |
|---|---|---|---|---|---|
| | memory | update | renorm | compression | enc/dec |
| bypass | no | no | no | no | yes |
| context | 3 bytes | yes | yes | best | no |
| G-pass | no | no | simple | average | no |

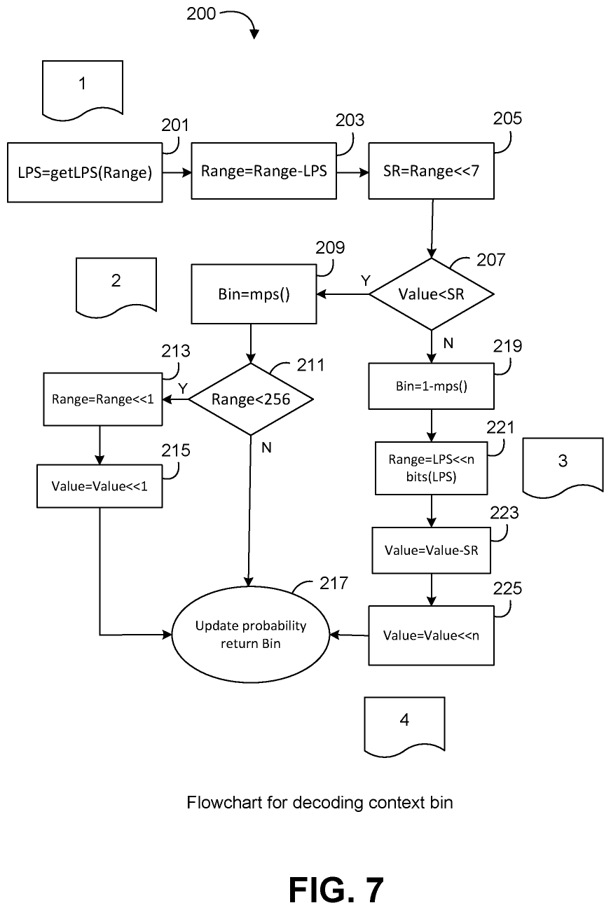

With reference to FIG. 7, an embodiment of a method 200 of decoding a context bin may include setting LPS=getLPS(Range) at block 201, setting Range=Range−LPS at block 203, and setting SR=Range<<7 at block 205. After block 205, the method 200 may proceed to determining if Value<SR at block 207 and, if so, setting Bin=mps( ) at block 209. After block 209, the method 200 may include determining if Range<256 at block 211 and, if so, setting Range=Range<<1 at block 213 and setting Value=Value<<1 at block 215 before updating the probability and returning Bin at block 217. If Range is not <256 at block 211, the method 200 may proceed to updating the probability and returning Bin at block 217. If Value is not <SR at block 207, the method may proceed to setting Bin=1−mps( ) at block 219, setting Range=LPS<<n bits(LPS) at block 221, setting Value=Value-SR at block 223, and setting Value=Value<<n at block 225. After block 225, the method may proceed to updating the probability and returning Bin at block 217.

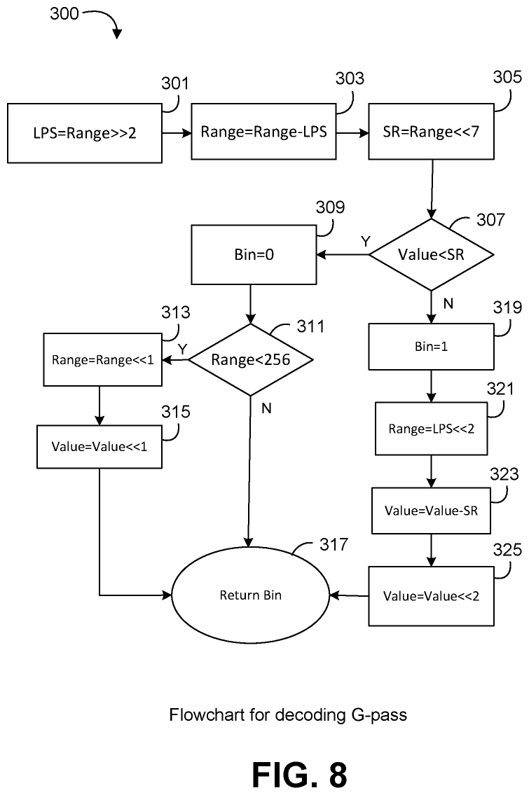

With reference to FIG. 8, an embodiment of a method 300 of decoding a G-pass may include setting LPS=Range>>2 at block 301, setting Range=Range−LPS at block 303, and setting SR=Range<<7 at block 305. After block 305, the method 300 may proceed to determining if Value<SR at block 307 and, if so, setting Bin=0 at block 309. After block 309, the method 300 may include determining if Range<256 at block 311 and, if so, setting Range=Range<<1 at block 313 and setting Value=Value<<1 at block 315 before returning Bin at block 317 (e.g., without updating the probability). If Range is not <256 at block 311, the method 300 may proceed to returning Bin at block 317. If Value is not <SR at block 307, the method may proceed to setting Bin=1 at block 319, setting Range=LPS<<2 at block 321, setting Value=Value-SR at block 323, and setting Value=Value<<2 at block 325. After block 325, the method may proceed to returning Bin at block 317.

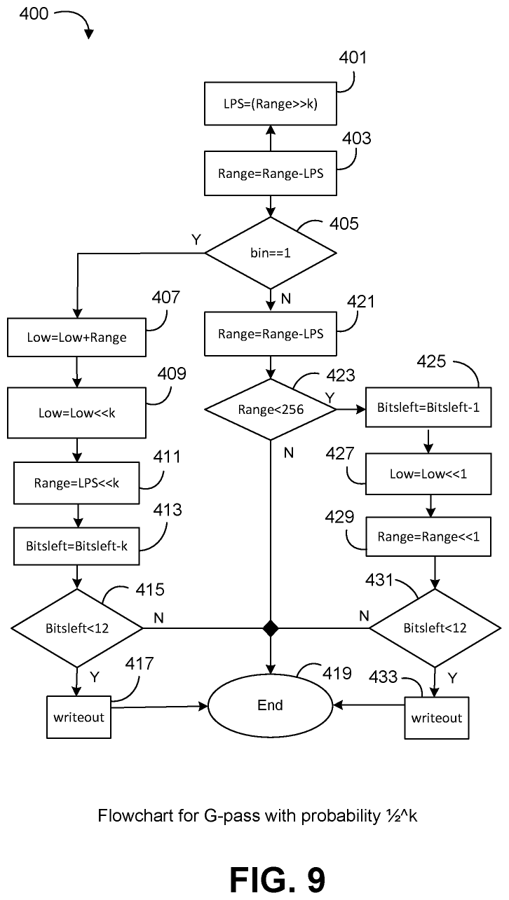

With reference to FIG. 9, an embodiment of a method 400 of encoding a G-pass with probability ½\hat{ }k may include setting LPS=(Range>>k) at block 401 and setting Range=Range-LPS at block 403. After block 403, the method 400 may include determining if bin==1 at block 405 and, if so, setting Low=Low+Range at block 407, setting Low=Low<<k at block 409, setting Range=LPS<<k at block 411, and setting Bitsleft=Bitsleft−k at block 413. After block 413, the method 400 may include determining if Bitsleft<12 at block 415 and, if so, performing a writeout at block 417 before ending at block 419 (e.g., without performing a probability update). If Bitsleft is not <12 at block 415, the method 400 may proceed to ending at block 419.

If the condition does not attain at block 405, the method 400 may proceed to setting Range=Range−LPS at block 421. After block 421, the method 400 may include determining if Range<256 at block 423 and, if so, setting Bitsleft=Bitsleft−1 at block 425, setting Low=Low<<1 at block 427, and setting Range=Range<<1 at block 429. If Range is not <256 at block 423, the method 400 may proceed to ending at block 419. After block 429, the method 400 may include determining if Bitsleft<12 at block 431 and, if so, performing a writeout at block 433 before ending at block 419. If Bitsleft is not <12 at block 431, the method 400 may proceed to ending at block 419.

For example, all or portions of the method 50, the method 100, the method 200, the method 300, the method 400, or any of the embodiments described herein, may be implemented on a machine readable medium (e.g., volatile memory, nonvolatile memory, magnetic drive, solid state drive, optical disc, flash drive, etc.). Embodiments or portions of the technology described herein may be implemented in firmware, applications (e.g., through an application programming interface (API)), or driver software running on an operating system (OS). Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Bypass/G-Pass Condition of the Choice Examples

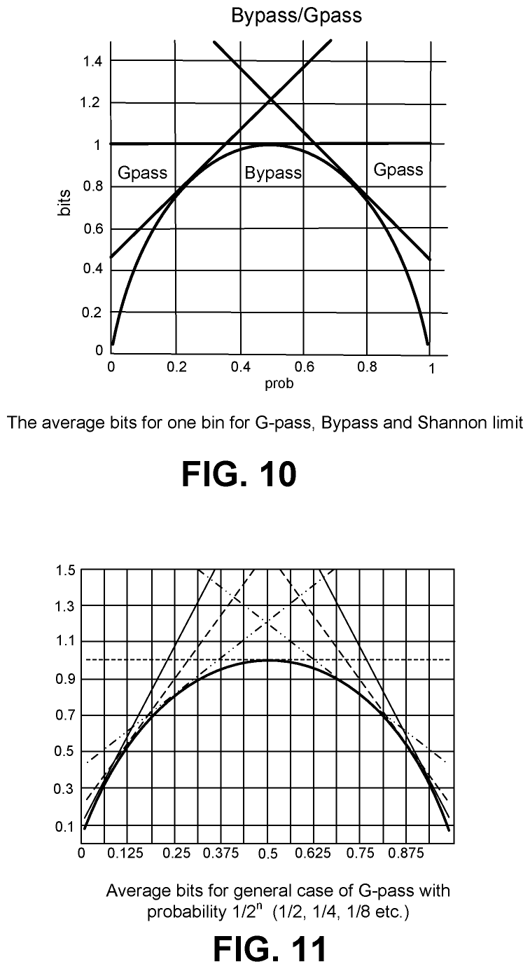

FIG. 10 shows the average bits for one bin for G-pass, Bypass and Shannon limit. Suppose p is probability of “1” but only bypass and G-pass (¼, ¾), (¾, ¼) are possible. For G-pass (¼, ¾) an average number of bits for one bin will be:

bits=−p log₂(¼)−(1 −p)log₂(¾)

For G-pass (¾, ¼) an average number of bits for one bin will be:

bits=−p log₂(¾)−(1 −p)log₂(¼)

And finally according to Shannon's formula, the entropy limit is:

bits=−p log₂(p)−(1 −p)log₂(1 −p)

Thus if probability is within the range [0.37,0.63] then conventional by-pass is better than G-pass. For intervals [0,0.37] and [0.63,1.0] G-pass is better.

FIG. 11 shows the average bits for a general case of G-pass with probability ½ⁿ (½, ¼, ⅛ etc.). In this case the point of intersection divided into two parts intervals which is optimal for G-pass with ½ⁿ and ½ⁿ⁺¹. This point can be found from the condition:

−p log₂(½ⁿ)−(1 −p)log₂(1 −½ⁿ)=−p log₂(½ⁿ⁺¹)−(1 −p)log₂(1 −½ⁿ⁺¹)

which has an explicit solution:

$$p = \frac{β}{1 + β} , where β = {log}_{2} ( \frac{1 - 1 / {2}^{n + 1}}{1 - 1 / {2}^{n}} )$$

This exact value can be substituted for the approximation:

$$p = \frac{1}{{2}^{n + 1} ln 2}$$

Or a more rigid:

$$p = \frac{1}{{2}^{n + 1 / 2}}$$

The last expression, however, has a clear geometric sense in terms of a measure of extent.

Interval Subdivision and Renormalization for Bypass and G-Pass Examples

For Bypass, Range should be divided by two and the next step is renormalization where Range should be multiplied by two to return (256, 512).

Table 3 shows interval sub-division and renormalization for Bypass, G-pass with probability ¼ if bin is equal “1,” and context bins.

TABLE 3

| Bypass | G-pass | Context bin |
|---|---|---|
| It is not | For “1” pass sub-division | For interval division |
| necessary to do | and renormalization always | needs LUT or |
| sub-division and | R=(R>>2)<<2 or | multiplication and |
| renormalization | R&=508 | probability calculation |
| due to it does not | For “0” : | For renormalization |
| change range | K= R−(R>>2) | number of |
| | Shift=(K<256) can be 0 or 1 | multiplications by |
| | R=K<<(shift) | 2 is calculated |
| | Can be written as one | using look-up table. |
| | formula without additional | |
| | variable. | |

G-Pass Instead of Bypass Examples

Some embodiments of G-pass may substitute for rare context models. Some embodiments allow a simplified encoding/decoding process and reduces memory utilization. G-pass may also be utilized instead bypass in some embodiments. If during encoding/decoding of some data bypass is used but real probability is different from ½, for example, G-pass can provide additional compression gain. VVC includes such data including, for example, SAO parameters and most significant bit for reminder (e.g., Rice code).

Various components of the systems described herein may be implemented in software, firmware, and/or hardware and/or any combination thereof. For example, various components of the systems or devices discussed herein may be provided, at least in part, by hardware of a computing System-on-a-Chip (SoC) such as may be found in a computing system such as, for example, a smart phone. Those skilled in the art may recognize that systems described herein may include additional components that have not been depicted in the corresponding figures. For example, the systems discussed herein may include additional components such as bit stream multiplexer or de-multiplexer modules and the like that have not been depicted in the interest of clarity.

While implementation of the example processes discussed herein may include the undertaking of all operations shown in the order illustrated, the present disclosure is not limited in this regard and, in various examples, implementation of the example processes herein may include only a subset of the operations shown, operations performed in a different order than illustrated, or additional operations.

In addition, any one or more of the operations discussed herein may be undertaken in response to instructions provided by one or more computer program products. Such program products may include signal bearing media providing instructions that, when executed by, for example, a processor, may provide the functionality described herein. The computer program products may be provided in any form of one or more machine-readable media. Thus, for example, a processor including one or more graphics processing unit(s) or processor core(s) may undertake one or more of the blocks of the example processes herein in response to program code and/or instructions or instruction sets conveyed to the processor by one or more machine-readable media. In general, a machine-readable medium may convey software in the form of program code and/or instructions or instruction sets that may cause any of the devices and/or systems described herein to implement at least portions of the operations discussed herein and/or any portions the devices, systems, or any module or component as discussed herein.

As used in any implementation described herein, the term “module” refers to any combination of software logic, firmware logic, hardware logic, and/or circuitry configured to provide the functionality described herein. The software may be embodied as a software package, code and/or instruction set or instructions, and “hardware”, as used in any implementation described herein, may include, for example, singly or in any combination, hardwired circuitry, programmable circuitry, state machine circuitry, fixed function circuitry, execution unit circuitry, and/or firmware that stores instructions executed by programmable circuitry. The modules may, collectively or individually, be embodied as circuitry that forms part of a larger system, for example, an integrated circuit (IC), system on-chip (SoC), and so forth.

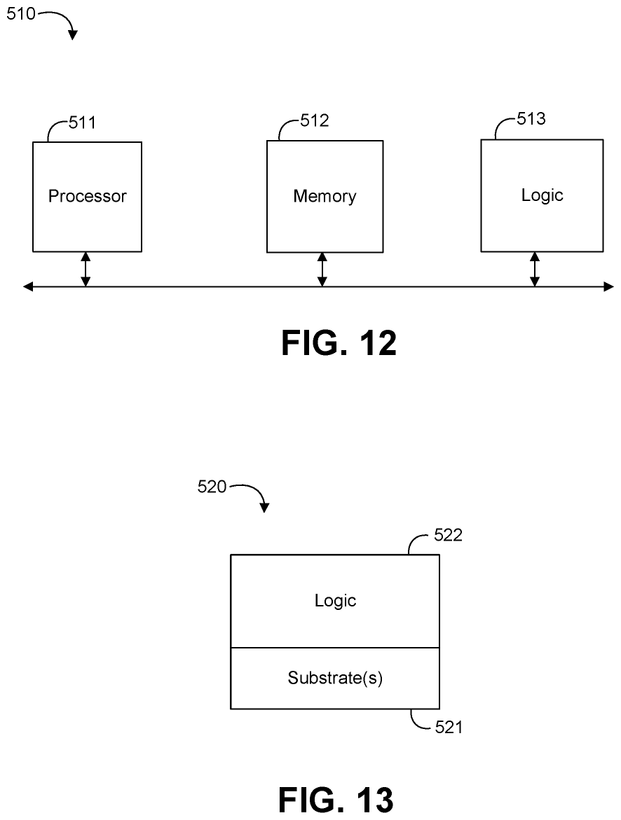

With reference to FIG. 12, an embodiment of an electronic system 510 may include memory 512 to store video data, a processor 511 coupled to the memory 512, and logic 513 coupled to the processor 511 and the memory 512. The logic 513 may be configured to utilize a generalized bypass bin to one or more of encode and decode the video data. For example, the logic 513 may be configured to select the generalized bypass bin to one or more of encode and decode a portion of the video data based on a data type associated with the portion of the video data. In some embodiments, the logic 513 may be further configured to one or more of encode and decode the video data based on two or more context models, determine a subset of context models of the two or more context models that are more rarely utilized in the video data, and substitute the generalized bypass bin for one or more of the context models from the subset. Additionally, or alternatively, the logic 513 may be configured to substitute the generalized bypass bin for a bypass bin. In some embodiments, the logic 513 may be further configured to compress the video data when the generalized bypass bin is utilized. The logic 513 may also be configured to one or more of encode and decode the video data based on a range division, and renormalize the range division based on a default number of bits when the generalized bypass bin is utilized.

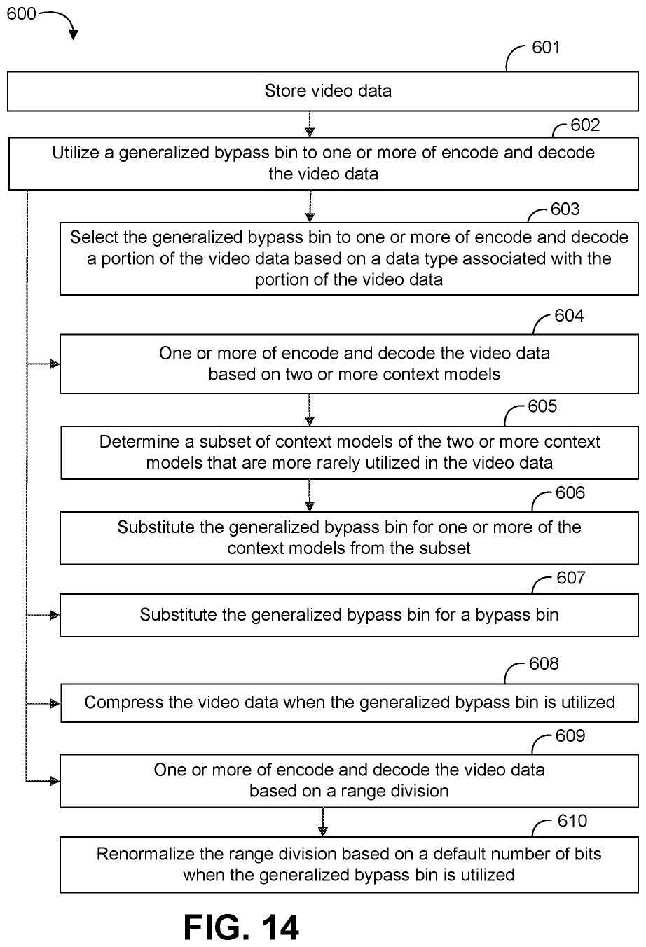

Advantageously, the system 510 may provide a reduction of the number of context models in arithmetic coding for video compression, which reduces look-up table size and a size of the memory 512 needed for probability storage. Some embodiments may further provide simplification of renormalization and interval division in the system 510. Advantageously, the logic 513 for the generalized bypass may have better coding efficiency compared to the conventional bypass mode. Use of embodiments of the generalized bypass in the system 510 may reduce the complexity of a video encoder or decoder implementation by replacing many context models with a generalized bypass, which is simpler to implement. Some embodiments may be included as part of a video standard, such as the VVC standard, and may advantageously reduce complexity of implementation of video encoder and decoder products based on the standard. In some embodiments, the logic 513 may implement one or more aspects of the method 50, the method 100, the method 200, the method 300, the method 400, the method 600 (see FIG. 14), or any of the embodiments described herein. For example, the logic 513 may be configured to provide a VVC codec to utilize the generalized pass bins.

Embodiments of each of the above processor 511, memory 512, logic 513, and other system components may be implemented in hardware, software, or any suitable combination thereof. For example, hardware implementations may include configurable logic such as, for example, programmable logic arrays (PLAs), field programmable gate arrays (FPGAs), complex programmable logic devices (CPLDs), or fixed-functionality logic hardware using circuit technology such as, for example, application specific integrated circuit (ASIC), complementary metal oxide semiconductor (CMOS) or transistor-transistor logic (TTL) technology, or any combination thereof. Embodiments of the processor 511 may include a general purpose processor, a special purpose processor, a central processor unit (CPU), a graphic processor, a general purpose controller, an execution unit, a special purpose controller, a general purpose controller, a micro-controller, etc. In some embodiments, the logic 513, may be located in, or co-located with, various components, including the processor 511 (e.g., on a same die).

Alternatively, or additionally, all or portions of these components may be implemented in one or more modules as a set of logic instructions stored in a machine- or computer-readable storage medium such as random access memory (RAM), read only memory (ROM), programmable ROM (PROM), firmware, flash memory, etc., to be executed by a processor or computing device. For example, computer program code to carry out the operations of the components may be written in any combination of one or more operating system (OS) applicable/appropriate programming languages, including an object-oriented programming language such as PYTHON, PERL, JAVA, SMALLTALK, C++, C# or the like and conventional procedural programming languages, such as the “C” programming language or similar programming languages. For example, the memory 512, firmware memory, persistent storage media, or other system memory may store a set of instructions which when executed by the processor 511 cause the system 510 to implement one or more components, features, or aspects of the system 510 (e.g., the logic 513, utilizing the generalized bypass bin to one or more of encode and decode the video data, etc.).

Turning now to FIG. 13, an embodiment of a video codec apparatus 520 may include one or more substrates 521, and logic 522 coupled to the one or more substrates 521. The logic 522 may be configured to utilize a generalized bypass bin to one or more of encode and decode the video data. For example, the logic 522 may be configured to select the generalized bypass bin to one or more of encode and decode a portion of the video data based on a data type associated with the portion of the video data. In some embodiments, the logic 522 may be further configured to one or more of encode and decode the video data based on two or more context models, determine a subset of context models of the two or more context models that are more rarely utilized in the video data, and substitute the generalized bypass bin for one or more of the context models from the subset. Additionally, or alternatively, the logic 522 may be configured to substitute the generalized bypass bin for a bypass bin. In some embodiments, the logic 522 may be further configured to compress the video data when the generalized bypass bin is utilized. The logic 522 may also be configured to one or more of encode and decode the video data based on a range division, and renormalize the range division based on a default number of bits when the generalized bypass bin is utilized.

In some embodiments, the logic 522 may implement one or more aspects of the method 50, the method 100, the method 200, the method 300, the method 400, the method 600, or any of the embodiments described herein. For example, the logic 522 may be configured to provide a VVC codec to utilize the generalized pass bins. For example, the logic 522 may be implemented on a semiconductor apparatus which may include the one or more substrates 521, with the logic 522 coupled to the one or more substrates 521. In some embodiments, the logic 522 may be at least partly implemented in one or more of configurable logic and fixed-functionality hardware logic on semiconductor substrate(s) 521 (e.g., silicon, sapphire, gallium-arsenide, etc.). For example, the logic 522 may include a transistor array and/or other integrated circuit components coupled to the substrate(s) 521 with transistor channel regions that are positioned within the substrate(s) 521. The interface between the logic 522 and the substrate(s) 521 may not be an abrupt junction. The logic 522 may also be considered to include an epitaxial layer that is grown on an initial wafer of the substrate(s) 521.

With reference to FIG. 14, an embodiment of a method 600 of processing video data may include storing video data at block 601, and utilizing a generalized bypass bin to one or more of encode and decode the video data at block 602. For example, the method 600 may further include selecting the generalized bypass bin to one or more of encode and decode a portion of the video data based on a data type associated with the portion of the video data at block 603. Some embodiments of the method 600 may also include one or more of encoding and decoding the video data based on two or more context models at block 604, determining a subset of context models of the two or more context models that are more rarely utilized in the video data at block 605, and substituting the generalized bypass bin for one or more of the context models from the subset at block 606. The method 600 may also include substituting the generalized bypass bin for a bypass bin at block 607. Some embodiments of the method 600 may further include compressing the video data when the generalized bypass bin is utilized at block 608. The method 600 may also include one or more of encoding and decoding the video data based on a range division at block 609, and renormalizing the range division based on a default number of bits when the generalized bypass bin is utilized at block 610.

For example, all or portions of the method 600 may be implemented on a machine readable medium (e.g., volatile memory, nonvolatile memory, magnetic drive, solid state drive, optical disc, flash drive, etc.). Embodiments or portions of the method 600 may also be implemented in firmware, applications (e.g., through an application programming interface (API)), or driver software running on an operating system (OS). Additionally, embodiments or portions of the method 600 may also include logic instructions such as assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

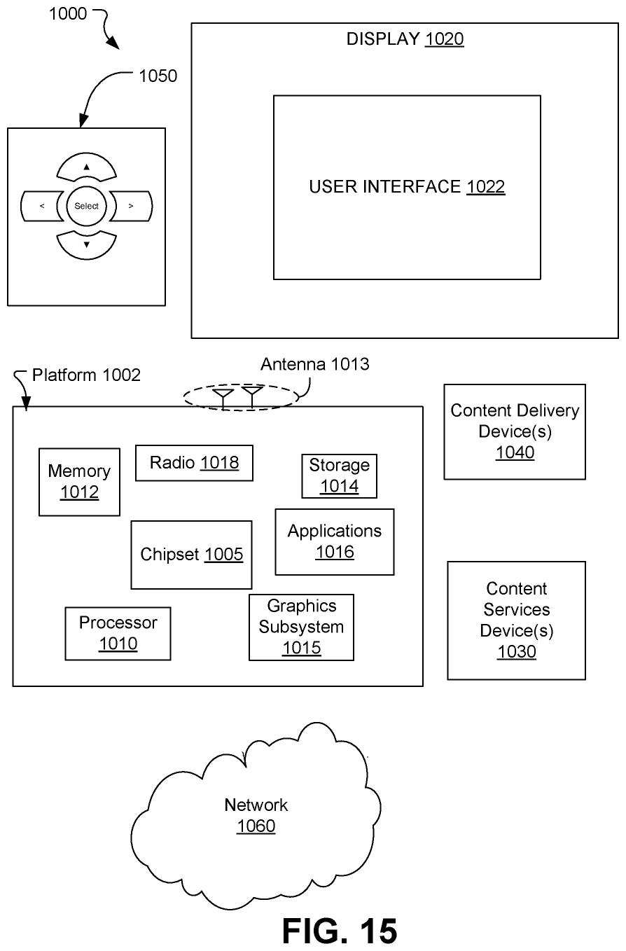

FIG. 15 is an illustrative diagram of an example system 1000, arranged in accordance with at least some implementations of the present disclosure. In various implementations, system 1000 may be a mobile system although system 1000 is not limited to this context. For example, system 1000 may be incorporated into a personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, cameras (e.g. point-and-shoot cameras, super-zoom cameras, digital single-lens reflex (DSLR) cameras), and so forth.

In various implementations, system 1000 includes a platform 1002 coupled to a display 1020. Platform 1002 may receive content from a content device such as content services device(s) 1030 or content delivery device(s) 1040 or other similar content sources. A navigation controller 1050 including one or more navigation features may be used to interact with, for example, platform 1002 and/or display 1020. Each of these components is described in greater detail below.

In various implementations, platform 1002 may include any combination of a chipset 1005, processor 1010, memory 1012, antenna 1013, storage 1014, graphics subsystem 1015, applications 1016 and/or radio 1018. Chipset 1005 may provide intercommunication among processor 1010, memory 1012, storage 1014, graphics subsystem 1015, applications 1016 and/or radio 1018. For example, chipset 1005 may include a storage adapter (not depicted) capable of providing intercommunication with storage 1014.

Processor 1010 may be implemented as a Complex Instruction Set Computer (CISC) or Reduced Instruction Set Computer (RISC) processors, x86 instruction set compatible processors, multi-core, or any other microprocessor or central processing unit (CPU). In various implementations, processor 1010 may be dual-core processor(s), dual-core mobile processor(s), and so forth.

Memory 1012 may be implemented as a volatile memory device such as, but not limited to, a Random Access Memory (RAM), Dynamic Random Access Memory (DRAM), or Static RAM (SRAM).

Storage 1014 may be implemented as a non-volatile storage device such as, but not limited to, a magnetic disk drive, optical disk drive, tape drive, an internal storage device, an attached storage device, flash memory, battery backed-up SDRAM (synchronous DRAM), and/or a network accessible storage device. In various implementations, storage 1014 may include technology to increase the storage performance enhanced protection for valuable digital media when multiple hard drives are included, for example.

Graphics subsystem 1015 may perform processing of images such as still or video for display. Graphics subsystem 1015 may be a graphics processing unit (GPU) or a visual processing unit (VPU), for example. An analog or digital interface may be used to communicatively couple graphics subsystem 1015 and display 1020. For example, the interface may be any of a High-Definition Multimedia Interface, DisplayPort, wireless HDMI, and/or wireless HD compliant techniques. Graphics subsystem 1015 may be integrated into processor 1010 or chipset 1005. In some implementations, graphics subsystem 1015 may be a stand-alone device communicatively coupled to chipset 1005.

The graphics and/or video processing techniques described herein may be implemented in various hardware architectures. For example, graphics and/or video functionality may be integrated within a chipset. Alternatively, a discrete graphics and/or video processor may be used. As still another implementation, the graphics and/or video functions may be provided by a general purpose processor, including a multi-core processor. In further embodiments, the functions may be implemented in a consumer electronics device.

Radio 1018 may include one or more radios capable of transmitting and receiving signals using various suitable wireless communications techniques. Such techniques may involve communications across one or more wireless networks. Example wireless networks include (but are not limited to) wireless local area networks (WLANs), wireless personal area networks (WPANs), wireless metropolitan area network (WMANs), cellular networks, and satellite networks. In communicating across such networks, radio 1018 may operate in accordance with one or more applicable standards in any version.

In various implementations, display 1020 may include any television type monitor or display. Display 1020 may include, for example, a computer display screen, touch screen display, video monitor, television-like device, and/or a television. Display 1020 may be digital and/or analog. In various implementations, display 1020 may be a holographic display. Also, display 1020 may be a transparent surface that may receive a visual projection. Such projections may convey various forms of information, images, and/or objects. For example, such projections may be a visual overlay for a mobile augmented reality (MAR) application. Under the control of one or more software applications 1016, platform 1002 may display user interface 1022 on display 1020.

In various implementations, content services device(s) 1030 may be hosted by any national, international and/or independent service and thus accessible to platform 1002 via the Internet, for example. Content services device(s) 1030 may be coupled to platform 1002 and/or to display 1020. Platform 1002 and/or content services device(s) 1030 may be coupled to a network 1060 to communicate (e.g., send and/or receive) media information to and from network 1060.

Content delivery device(s) 1040 also may be coupled to platform 1002 and/or to display 1020.

In various implementations, content services device(s) 1030 may include a cable television box, personal computer, network, telephone, Internet enabled devices or appliance capable of delivering digital information and/or content, and any other similar device capable of uni-directionally or bi-directionally communicating content between content providers and platform 1002 and/display 1020, via network 1060 or directly. It will be appreciated that the content may be communicated uni-directionally and/or bi-directionally to and from any one of the components in system 1000 and a content provider via network 1060. Examples of content may include any media information including, for example, video, music, medical and gaming information, and so forth.

Content services device(s) 1030 may receive content such as cable television programming including media information, digital information, and/or other content. Examples of content providers may include any cable or satellite television or radio or Internet content providers. The provided examples are not meant to limit implementations in accordance with the present disclosure in any way.

In various implementations, platform 1002 may receive control signals from navigation controller 1050 having one or more navigation features. The navigation features may be used to interact with user interface 1022, for example. In various embodiments, navigation may be a pointing device that may be a computer hardware component (specifically, a human interface device) that allows a user to input spatial (e.g., continuous and multi-dimensional) data into a computer. Many systems such as graphical user interfaces (GUI), and televisions and monitors allow the user to control and provide data to the computer or television using physical gestures.

Movements of the navigation features may be replicated on a display (e.g., display 1020) by movements of a pointer, cursor, focus ring, or other visual indicators displayed on the display. For example, under the control of software applications 1016, the navigation features located on navigation may be mapped to virtual navigation features displayed on user interface 1022, for example. In various embodiments, may not be a separate component but may be integrated into platform 1002 and/or display 1020. The present disclosure, however, is not limited to the elements or in the context shown or described herein.

In various implementations, drivers (not shown) may include technology to enable users to instantly turn on and off platform 1002 like a television with the touch of a button after initial boot-up, when enabled, for example. Program logic may allow platform 1002 to stream content to media adaptors or other content services device(s) 1030 or content delivery device(s) 1040 even when the platform is turned “off” In addition, chipset 1005 may include hardware and/or software support for 5.1 surround sound audio and/or high definition 7.1 surround sound audio, for example. Drivers may include a graphics driver for integrated graphics platforms. In various embodiments, the graphics driver may include a peripheral component interconnect (PCI) Express graphics card.

In various implementations, any one or more of the components shown in system 1000 may be integrated. For example, platform 1002 and content services device(s) 1030 may be integrated, or platform 1002 and content delivery device(s) 1040 may be integrated, or platform 1002, content services device(s) 1030, and content delivery device(s) 1040 may be integrated, for example. In various embodiments, platform 1002 and display 1020 may be an integrated unit. Display 1020 and content service device(s) 1030 may be integrated, or display 1020 and content delivery device(s) 1040 may be integrated, for example. These examples are not meant to limit the present disclosure.

In various embodiments, system 1000 may be implemented as a wireless system, a wired system, or a combination of both. When implemented as a wireless system, system 1000 may include components and interfaces suitable for communicating over a wireless shared media, such as one or more antennas, transmitters, receivers, transceivers, amplifiers, filters, control logic, and so forth. An example of wireless shared media may include portions of a wireless spectrum, such as the RF spectrum and so forth. When implemented as a wired system, system 1000 may include components and interfaces suitable for communicating over wired communications media, such as input/output (I/O) adapters, physical connectors to connect the I/O adapter with a corresponding wired communications medium, a network interface card (NIC), disc controller, video controller, audio controller, and the like. Examples of wired communications media may include a wire, cable, metal leads, printed circuit board (PCB), backplane, switch fabric, semiconductor material, twisted-pair wire, co-axial cable, fiber optics, and so forth.

Platform 1002 may establish one or more logical or physical channels to communicate information. The information may include media information and control information. Media information may refer to any data representing content meant for a user. Examples of content may include, for example, data from a voice conversation, videoconference, streaming video, electronic mail (“email”) message, voice mail message, alphanumeric symbols, graphics, image, video, text and so forth. Data from a voice conversation may be, for example, speech information, silence periods, background noise, comfort noise, tones and so forth. Control information may refer to any data representing commands, instructions or control words meant for an automated system. For example, control information may be used to route media information through a system, or instruct a node to process the media information in a predetermined manner. The embodiments, however, are not limited to the elements or in the context shown or described in FIG. 15.

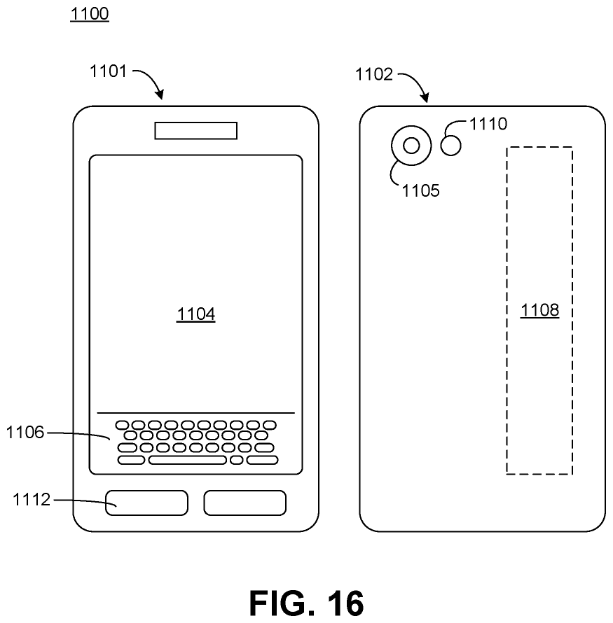

As described above, system 1000 may be embodied in varying physical styles or form factors. FIG. 16 illustrates an example small form factor device 1100, arranged in accordance with at least some implementations of the present disclosure. In some examples, system 1000 may be implemented via device 1100. In other examples, system 100 or portions thereof may be implemented via device 1100. In various embodiments, for example, device 1100 may be implemented as a mobile computing device a having wireless capabilities. A mobile computing device may refer to any device having a processing system and a mobile power source or supply, such as one or more batteries, for example.

Examples of a mobile computing device may include a personal computer (PC), laptop computer, ultra-laptop computer, tablet, touch pad, portable computer, handheld computer, palmtop computer, personal digital assistant (PDA), cellular telephone, combination cellular telephone/PDA, smart device (e.g., smart phone, smart tablet or smart mobile television), mobile internet device (MID), messaging device, data communication device, cameras, and so forth.

Examples of a mobile computing device also may include computers that are arranged to be worn by a person, such as a wrist computers, finger computers, ring computers, eyeglass computers, belt-clip computers, arm-band computers, shoe computers, clothing computers, and other wearable computers. In various embodiments, for example, a mobile computing device may be implemented as a smart phone capable of executing computer applications, as well as voice communications and/or data communications. Although some embodiments may be described with a mobile computing device implemented as a smart phone by way of example, it may be appreciated that other embodiments may be implemented using other wireless mobile computing devices as well. The embodiments are not limited in this context.

As shown in FIG. 16, device 1100 may include a housing with a front 1101 and a back 1102. Device 1100 includes a display 1104, an input/output (I/O) device 1106, and an integrated antenna 1108. Device 1100 also may include navigation features 1112. I/O device 1106 may include any suitable I/O device for entering information into a mobile computing device. Examples for I/O device 1106 may include an alphanumeric keyboard, a numeric keypad, a touch pad, input keys, buttons, switches, microphones, speakers, voice recognition device and software, and so forth. Information also may be entered into device 1100 by way of microphone (not shown), or may be digitized by a voice recognition device. As shown, device 1100 may include a camera 1105 (e.g., including a lens, an aperture, and an imaging sensor) and a flash 1110 integrated into back 1102 (or elsewhere) of device 1100. In other examples, camera 1105 and flash 1110 may be integrated into front 1101 of device 1100 or both front and back cameras may be provided. Camera 1105 and flash 1110 may be components of a camera module to originate image data processed into streaming video that is output to display 1104 and/or communicated remotely from device 1100 via antenna 1108 for example.

The system 1000 and/or the device 1100 may include one or more features or aspects of the various embodiments described herein, including those described in connection with the method 50, the method 100, the method 200, the method 300, the method 400, the method 600, or any of the embodiments described herein.

### ADDITIONAL NOTES AND EXAMPLES

Example 1 includes an electronic system, comprising memory to store video data, a processor coupled to the memory; and logic coupled to the processor and the memory, the logic to utilize a generalized bypass bin to one or more of encode and decode the video data.

Example 2 includes the system of Example 1, wherein the logic is further to select the generalized bypass bin to one or more of encode and decode a portion of the video data based on a data type associated with the portion of the video data.

Example 3 includes the system of Example 1, wherein the logic is further to one or more of encode and decode the video data based on two or more context models, determine a subset of context models of the two or more context models that are more rarely utilized in the video data; and substitute the generalized bypass bin for one or more of the context models from the subset.

Example 4 includes the system of any of Examples 1 to 3, wherein the logic is further to compress the video data when the generalized bypass bin is utilized.

Example 5 includes the system of any of Examples 1 to 4, wherein the logic is further to one or more of encode and decode the video data based on a range division; and renormalize the range division based on a default number of bits when the generalized bypass bin is utilized.

Example 6 includes the system of any of Examples 1 to 5, wherein the logic is further to substitute the generalized bypass bin for a bypass bin.

Example 7 includes the system of any of Examples 1 to 6, wherein the logic is further to provide a Versatile Video Coding (VVC) codec to utilize the generalized pass bins.

Example 8 includes a method of processing video data, comprising storing video data; and utilizing a generalized bypass bin to one or more of encode and decode the video data.

Example 9 includes the method of Example 8, further comprising selecting the generalized bypass bin to one or more of encode and decode a portion of the video data based on a data type associated with the portion of the video data.

Example 10 includes the method of Example 8, further comprising one or more of encoding and decoding the video data based on two or more context models, determining a subset of context models of the two or more context models that are more rarely utilized in the video data; and substituting the generalized bypass bin for one or more of the context models from the subset.

Example 11 includes the method of any of Examples 8 to 10, further comprising compressing the video data when the generalized bypass bin is utilized.

Example 12 includes the method of any of Examples 8 to 11, further comprising one or more of encoding and decoding the video data based on a range division; and renormalizing the range division based on a default number of bits when the generalized bypass bin is utilized.

Example 13 includes the method of any of Examples 8 to 12, further comprising substituting the generalized bypass bin for a bypass bin.

Example 14 includes at least one non-transitory machine readable medium comprising a plurality of instructions that, in response to being executed on a computing device, cause the computing device to utilize a generalized bypass bin to one or more of encode and decode the video data.

Example 15 includes the at least one non-transitory machine readable medium of Example 14, comprising a plurality of further instructions that, in response to being executed on the computing device, cause the computing device to select the generalized bypass bin to one or more of encode and decode a portion of the video data based on a data type associated with the portion of the video data.

Example 16 includes the at least one non-transitory machine readable medium of Example 14, comprising a plurality of further instructions that, in response to being executed on the computing device, cause the computing device to one or more of encode and decode the video data based on two or more context models, determine a subset of context models of the two or more context models that are more rarely utilized in the video data; and substitute the generalized bypass bin for one or more of the context models from the subset.

Example 17 includes the at least one non-transitory machine readable medium of any of Examples 14 to 16, comprising a plurality of further instructions that, in response to being executed on the computing device, cause the computing device to compress the video data when the generalized bypass bin is utilized.

Example 18 includes the at least one non-transitory machine readable medium of any of Examples 14 to 17, comprising a plurality of further instructions that, in response to being executed on the computing device, cause the computing device to one or more of encode and decode the video data based on a range division; and renormalize the range division based on a default number of bits when the generalized bypass bin is utilized.

Example 19 includes the at least one non-transitory machine readable medium of any of Examples 14 to 18, comprising a plurality of further instructions that, in response to being executed on the computing device, cause the computing device to substitute the generalized bypass bin for a bypass bin.

Example 20 includes a video codec apparatus, comprising one or more substrates; and logic coupled to the one or more substrates, the logic to utilize a generalized bypass bin to one or more of encode and decode the video data.

Example 21 includes the apparatus of Example 20, wherein the logic is further to select the generalized bypass bin to one or more of encode and decode a portion of the video data based on a data type associated with the portion of the video data.

Example 22 includes the apparatus of Example 20, wherein the logic is further to one or more of encode and decode the video data based on two or more context models, determine a subset of context models of the two or more context models that are more rarely utilized in the video data; and substitute the generalized bypass bin for one or more of the context models from the subset.

Example 23 includes the apparatus of any of Examples 20 to 22, wherein the logic is further to compress the video data when the generalized bypass bin is utilized.

Example 24 includes the apparatus of any of Examples 20 to 23, wherein the logic is further to one or more of encode and decode the video data based on a range division; and renormalize the range division based on a default number of bits when the generalized bypass bin is utilized.

Example 25 includes the apparatus of any of Examples 20 to 24, wherein the logic is further to substitute the generalized bypass bin for a bypass bin.

Example 26 includes a video processing apparatus, comprising means for storing video data; and means for utilizing a generalized bypass bin to one or more of encode and decode the video data.

Example 27 includes the apparatus of Example 26, further comprising means for selecting the generalized bypass bin to one or more of encode and decode a portion of the video data based on a data type associated with the portion of the video data.

Example 28 includes the apparatus of Example 26, further comprising means for one or more of encoding and decoding the video data based on two or more context models, means for determining a subset of context models of the two or more context models that are more rarely utilized in the video data; and means for substituting the generalized bypass bin for one or more of the context models from the subset.

Example 29 includes the apparatus of any of Examples 26 to 28, further comprising means for compressing the video data when the generalized bypass bin is utilized.

Example 30 includes the apparatus of any of Examples 26 to 29, further comprising means for one or more of encoding and decoding the video data based on a range division; and means for renormalizing the range division based on a default number of bits when the generalized bypass bin is utilized.

Example 31 includes the apparatus of any of Examples 26 to 30, further comprising means for substituting the generalized bypass bin for a bypass bin.

Example 32 includes the system of Example 1, wherein the logic is further to implement one or more aspects of the method 50.

Example 33 includes the system of any of Examples 1 and 32, wherein the logic is further to implement one or more aspects of the method 100.

Example 34 includes the system of any of Examples 1 and 32 to 33, wherein the logic is further to implement one or more aspects of the method 200.

Example 35 includes the system of any of Examples 1 and 32 to 34, wherein the logic is further to implement one or more aspects of the method 300.

Example 36 includes the system of any of Examples 1 and 32 to 35, wherein the logic is further to implement one or more aspects of the method 400.

Example 37 includes the system of any of Examples 1 and 32 to 36, wherein the logic is further to provide a Versatile Video Coding (VVC) codec to utilize the generalized pass bins.

Example 38 includes a method of Example 8, comprising implementing one or more aspects of the method 600.

Example 39 includes the method of Example 38, further comprising implementing one or more aspects of the method 50.

Example 40 includes the method of any of Examples 38 to 39, further comprising implementing one or more aspects of the method 100.

Example 41 includes the method of any of Examples 38 to 40, further comprising implementing one or more aspects of the method 200.

Example 42 includes the method of any of Examples 38 to 41, further comprising implementing one or more aspects of the method 300.

Example 43 includes the method of any of Examples 38 to 42, further comprising implementing one or more aspects of the method 400.

Example 44 includes the method of any of Examples 38 to 43, further comprising providing a VVC codec to utilize the generalized pass bins.

Example 45 includes the machine readable medium of Example 15, comprising a plurality of further instructions that, in response to being executed on the computing device, cause the computing device to implement one or more aspects of the method 600.

Example 46 includes the machine readable medium of Example 45, comprising a plurality of further instructions that, in response to being executed on the computing device, cause the computing device to implement one or more aspects of the method 50.

Example 47 includes the machine readable medium of any of Examples 45 to 46, comprising a plurality of further instructions that, in response to being executed on the computing device, cause the computing device to implement one or more aspects of the method 100.

Example 48 includes the machine readable medium of any of Examples 45 to 47, comprising a plurality of further instructions that, in response to being executed on the computing device, cause the computing device to implement one or more aspects of the method 200.

Example 49 includes the machine readable medium of any of Examples 45 to 48, comprising a plurality of further instructions that, in response to being executed on the computing device, cause the computing device to implement one or more aspects of the method 300.

Example 50 includes the machine readable medium of any of Examples 45 to 49, comprising a plurality of further instructions that, in response to being executed on the computing device, cause the computing device to implement one or more aspects of the method 400.

Example 51 includes the machine readable medium of any of Examples 45 to 50, comprising a plurality of further instructions that, in response to being executed on the computing device, cause the computing device to provide a VVC codec to utilize the generalized pass bins.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as IP cores may be stored on a tangible, machine readable medium and supplied to various customers or manufacturing facilities to load into the fabrication machines that actually make the logic or processor.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the embodiments are not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

1-25. (canceled)

26. An electronic system, comprising:
memory to store video data;
a processor coupled to the memory; and
logic coupled to the processor and the memory, the logic to:
utilize a generalized bypass bin to one or more of encode and decode the video data.

27. The system of claim 26, wherein the logic is further to:
select the generalized bypass bin to one or more of encode and decode a portion of the video data based on a data type associated with the portion of the video data.

28. The system of claim 26, wherein the logic is further to:
one or more of encode and decode the video data based on two or more context models;
determine a subset of context models of the two or more context models that are more rarely utilized in the video data; and
substitute the generalized bypass bin for one or more of the context models from the subset.

29. The system of claim 26, wherein the logic is further to:
compress the video data when the generalized bypass bin is utilized.

30. The system of claim 26, wherein the logic is further to:
one or more of encode and decode the video data based on a range division; and
renormalize the range division based on a default number of bits when the generalized bypass bin is utilized.

31. The system of claim 26, wherein the logic is further to:
substitute the generalized bypass bin for a bypass bin.

32. The system of claim 26, wherein the logic is further to:
provide a Versatile Video Coding (VVC) codec to utilize the generalized pass bins.

33. A method of processing video data, comprising:
storing video data; and
utilizing a generalized bypass bin to one or more of encode and decode the video data.

34. The method of claim 33, further comprising:
selecting the generalized bypass bin to one or more of encode and decode a portion of the video data based on a data type associated with the portion of the video data.

35. The method of claim 33, further comprising:
one or more of encoding and decoding the video data based on two or more context models;
determining a subset of context models of the two or more context models that are more rarely utilized in the video data; and
substituting the generalized bypass bin for one or more of the context models from the subset.

36. The method of claim 33, further comprising:
compressing the video data when the generalized bypass bin is utilized.

37. The method of claim 33, further comprising:
one or more of encoding and decoding the video data based on a range division; and
renormalizing the range division based on a default number of bits when the generalized bypass bin is utilized.

38. The method of claim 33, further comprising:
substituting the generalized bypass bin for a bypass bin.

39. At least one non-transitory machine readable medium comprising a plurality of instructions that, in response to being executed on a computing device, cause the computing device to:
utilize a generalized bypass bin to one or more of encode and decode the video data.

40. The at least one non-transitory machine readable medium of claim 39, comprising a plurality of further instructions that, in response to being executed on the computing device, cause the computing device to:
select the generalized bypass bin to one or more of encode and decode a portion of the video data based on a data type associated with the portion of the video data.

41. The at least one non-transitory machine readable medium of claim 39, comprising a plurality of further instructions that, in response to being executed on the computing device, cause the computing device to:
one or more of encode and decode the video data based on two or more context models;
determine a subset of context models of the two or more context models that are more rarely utilized in the video data; and
substitute the generalized bypass bin for one or more of the context models from the subset.

42. The at least one non-transitory machine readable medium of claim 39, comprising a plurality of further instructions that, in response to being executed on the computing device, cause the computing device to:
compress the video data when the generalized bypass bin is utilized.

43. The at least one non-transitory machine readable medium of claim 39, comprising a plurality of further instructions that, in response to being executed on the computing device, cause the computing device to:
one or more of encode and decode the video data based on a range division; and
renormalize the range division based on a default number of bits when the generalized bypass bin is utilized.

44. The at least one non-transitory machine readable medium of claim 39, comprising a plurality of further instructions that, in response to being executed on the computing device, cause the computing device to:
substitute the generalized bypass bin for a bypass bin.

45. A video codec apparatus, comprising:
one or more substrates; and
logic coupled to the one or more substrates, the logic to:
utilize a generalized bypass bin to one or more of encode and decode the video data.

46. The apparatus of claim 45, wherein the logic is further to:
select the generalized bypass bin to one or more of encode and decode a portion of the video data based on a data type associated with the portion of the video data.

47. The apparatus of claim 45, wherein the logic is further to:
one or more of encode and decode the video data based on two or more context models;
determine a subset of context models of the two or more context models that are more rarely utilized in the video data; and
substitute the generalized bypass bin for one or more of the context models from the subset.

48. The apparatus of claim 45, wherein the logic is further to:
compress the video data when the generalized bypass bin is utilized.

49. The apparatus of claim 45, wherein the logic is further to:
one or more of encode and decode the video data based on a range division; and
renormalize the range division based on a default number of bits when the generalized bypass bin is utilized.

50. The apparatus of claim 45, wherein the logic is further to:
substitute the generalized bypass bin for a bypass bin.
